(19) United States
(12) Patent Application Publication
(10) Pub. No.: US 2014/0182661 A1
(43) Pub. Date: Jul. 3, 2014

(54) PHOTOVOLTAIC MODULE FRAME WITH IMPROVED BONDABILITY

(71) Applicant: SUNPOWER CORPORATION, San Jose, CA (US)

(72) Inventor: Zachary Kinyon, Walnut Creek, CA (US)

(73) Assignee: SUNPOWER CORPORATION, San Jose, CA (US)

(21) Appl. No.: 13/730,601

(22) Filed: Dec. 28, 2012

(51) Int. Cl. H01L 31/042

(52) U.S. Cl. CPC H01L 31/0422
USPC 136/251

(57) ABSTRACT

A photovoltaic module can be formed with a laminate bonded to frame members. The frame members can extend around the periphery of the laminate. The frame members can include surface features which increase the surface area of the portion of the frame member bonded to the laminate, and thereby improve the bond strength between the frame member and the laminate. Further, the surface features can extend generally longitudinally along the peripheral edges of the laminate, thereby helping to guide a flow of liquid adhesive, during the manufacturing process, along longitudinal direction and thus reduce the amount of adhesive that leaks out onto the laminate during the manufacturing process.

### TECHNICAL FIELD

Embodiments of the subject matter described herein relate generally to solar collectors. More particularly, embodiments of the subject matter relate to photovoltaic modules with frames provided with enhanced durability.

### BACKGROUND

### Description of the Related Art

Solar power has long been viewed as an important alternative energy source. To this end, substantial efforts and investments have been made to develop and improve upon solar energy collection technology.

Solar photovoltaic systems (or simply “photovoltaic systems”) employ solar panels made of silicon or other materials (e.g., III-V cells such as GaAs) to convert sunlight into electricity. Photovoltaic systems typically include a plurality of photovoltaic (PV) modules (or “solar tiles”) interconnected with wiring to one or more appropriate electrical components (e.g., switches, inverters, junction boxes, etc.). PV modules typically consists of a PV laminate including an assembly of crystalline or amorphous semiconductor devices (“PV cells”) electrically interconnected and encapsulated within a weather-proof barrier. One or more electrical conductors are carried by the PV laminate through which the solar-generated current is conducted.

Regardless of an exact construction of the PV laminate, most PV applications entail placing an array of PV modules at the installation site in a location where sunlight is readily present. This is especially true for commercial or industrial applications in which a relatively large number of PV modules are desirable for generating substantial amounts of energy, with the rooftop of the commercial building providing a convenient surface at which the PV modules can be placed.

As a point of reference, many commercial buildings have large, flat roofs that are inherently conducive to placement of a PV module array, and are the most efficient use of existing space. While rooftop installation is thus highly viable, certain environment constraints must be addressed.

For example, PV laminates are generally flat or planar. Thus, at some latitudes, it can be sufficiently efficient to install PV laminates in a precisely horizontal orientation. At other latitudes, it is more efficient to install PV laminates at a tilted angle, relative to a flat rooftop (i.e., toward the southern sky for northern hemisphere installation, or toward the northern sky for southern hemisphere installations). PV laminates and/or PV modules can also be installed on some tracking systems which tilt the modules actively to track to the sun as the sun moves across the sky. Additionally, PV laminates should be installed with frames that are sufficiently strong to withstand any wind forces.

In light of the above, PV modules usually include robust frames for maintaining the PV laminate relative to the installation surface (e.g., penetrating-type mounting in which bolts are driven through the rooftop to attach the framework and/or auxiliary connectors to the rooftop; non-penetrating mounting in which auxiliary components interconnect PV modules to one another; etc.). Thus, some traditional PV modules employ an extruded aluminum frame that supports the entire perimeter of the corresponding PV laminate. A lip of the aluminum frame extends over and captures an upper surface of the PV laminate.

### SUMMARY OF THE INVENTIONS

An aspect of at least one of the inventions disclosed herein includes the realization that some known PV module designs have suffered from premature failures related to the bonding of PV frames to PV laminates. Generally, in the design of PV modules, part of a PV laminate is inserted into a channel formed on a frame member to provide secure attachment for supporting the PV module in the desired orientation. However, all of this space dedicated to the frame of the PV module generally cannot be used for power generation purposes. Thus, in many PV module designs, the size of the frame, and more specifically, the depth of the channel note above, is minimized so to maximize the amount of sunlight that can be captured for energy production.

As the size of the channel noted above is reduced, the magnitude of surface area available for bonding, and therefore the ultimate boding strength is also reduced. Insufficient bonding strength leads to failure. For example, generally, the strength of an adhesive bond is proportional to the total surface area of the components in contact with the adhesive. Thus, the holding strength of a bond between a PV frame and laminate can be calculated based on the surface area of the mating surfaces, respectfully, of the PV laminate and the frame.

An aspect of at least one of the inventions disclosed herein includes the realization that adding surface features to the inner surfaces of the frame members of a PV module can increase the bonding strength provided at the mating surfaces of the PV laminate and the PV frame by increasing the total surface area of the inner surfaces of the frame. Although it is technically possible to provide similar surface features at the peripheral edge of a PV laminate, the manufacturing costs of doing so is, presently, quite high. On the other hand, frames for PV modules can be easily made with various different manufacturing techniques, such as aluminum extrusions. Thus, some surface features can be added to existing frame designs by merely changing the dyes used for the extrusions without significantly increasing material costs.

Another aspect of at least one of the inventions disclosed herein includes the realization that after an adhesive has been applied to the mating surfaces of a laminate and a PV frame, and the assembled structure is arranged for curing, the PV laminate can sag under its own weight and cause a defect in the adhesive. More specifically, the sagging of the PV laminate relative to its frame can cause a portion of the mating surfaces of the frame and the laminate to be pressed together, thereby squeezing adhesive out of the space between the two juxtaposed surfaces of the laminate and the frame, and generating an excessively thin area of adhesive. Such an excessively thin area adhesive can more easily result in a void or crack in the adhesive which can then propagate under fatigue loading.

Thus, in accordance with an embodiment, a photovoltaic solar collector can comprise a photo electronic device configured to convert solar radiation into electrical power. The photo electronic device can have a photo-sensitive surface arranged to be exposable to sunlight and a peripheral edge. At least a first frame member can be connected to the peripheral edge of the photo electronic device. The first frame member can comprise at least a first surface bonded to the peripheral edge of the photo electronic device, at least one of the peripheral edge and the first surface being non planar.

In accordance with another embodiment, a photovoltaic solar collector can comprise a photo electronic device configured to convert solar radiation into electrical power. The photo electronic device can have a photo-sensitive surface arranged to be exposable to sunlight and a planar peripheral edge having an upper peripheral edge surface and a lower peripheral edge surface. A frame can extend longitudinally along the peripheral edge of the photo electronic device. The frame can comprise a channel portion comprising an upper flange and a lower flange, the upper flange having an upper flange inner surface, the lower flange having a lower flange inner surface, wherein at least one of the upper flange inner surface and the lower flange inner surface having longitudinally extending ribs sized and shaped so as to increase the surface area of the inner surface compared to a planar surface having a same footprint, and wherein the upper and lower flange inner surfaces are bonded to the upper and lower peripheral edge surfaces, respectively.

In accordance with yet another embodiment, a photovoltaic solar collector can comprise a photo electronic device configured to convert solar radiation into electrical power. The photo electronic device can have a photo-sensitive surface arranged to be exposable to sunlight and a planar peripheral edge. A frame can extend longitudinally along the peripheral edge of the photo electronic device. The frame can comprise a channel having an inner surface bonded to the planar peripheral edge and means for providing increased surface area of the inner surface of the channel that is bonded to the peripheral edge.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a schematic diagram of a photovoltaic laminate being supported during a manufacturing process and including two frame members having liquid adhesive disposed therein adjacent to opposite peripheral edges of the PV laminate;

FIG. 2 is a schematic view of the arrangement of FIG. 1 after the frame members have been moved towards the PV laminate so as to position surfaces of a peripheral edge of the PV laminate so as to be juxtaposed to inner surfaces of the frame members;

FIG. 3 is a schematic view of a position of the resulting PV module during the curing phase of manufacture;

FIG. 4 is a schematic top plan view of a portion of the PV laminate from FIG. 3, with a frame member removed, and illustrating areas of different thickness of adhesive resulting from the manufacturing process;

FIG. 5 is a sectional view of a frame member having surface features in accordance with an embodiment.

FIG. 6 is a perspective view of the frame member of FIG. 5;

FIG. 7 is a top plan view of a complete PV module having a PV laminate and a plurality of frame members extending around the periphery of the PV laminate;

FIG. 8 is an enlarged sectional view of an upper portion of an embodiment of a frame member having surface features on a lower surface of a channel portion of a frame;

FIG. 9 is a sectional view of a further embodiment of a frame member having surface features on both upper and lower surfaces of the channel portion of the frame;

FIG. 10 is a sectional view of a further embodiment of a frame member having surface features on a lower surface of the channel portion of the frame;

FIG. 11 is a further embodiment of the frame illustrated in FIG. 10 having surface features on both upper and lower surfaces of the channel portion of the frame;

FIG. 12 is a sectional view of a further embodiment of the frame member having surface features on a lower surface of the channel portion;

FIG. 13 is a further embodiment of the frame member illustrated in FIG. 12 having surface features on both upper and lower surfaces of the channel portion.

### DETAILED DESCRIPTION OF THE PREFERRED EMBODIMENT

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature.

“Locating connector”—The following description refers to devices or features being connected with a “locating connector”. As used herein, unless expressly stated otherwise, “locating connector” means that one element/node/feature is directly or indirectly joined to (or directly or indirectly communicates with) another element/node/feature with a mechanism that connects and also provides a locating function, such as for example but without limitation, alignment of elements/nodes/features or enhancing contact between two elements/nodes/features.

“Adjust”—Some elements, components, and/or features are described as being adjustable or adjusted. As used herein, unless expressly stated otherwise, “adjust” means to position, modify, alter, or dispose an element or component or portion thereof as suitable to the circumstance and embodiment. In certain cases, the element or component, or portion thereof, can remain in an unchanged position, state, and/or condition as a result of adjustment, if appropriate or desirable for the embodiment under the circumstances. In some cases, the element or component can be altered, changed, or modified to a new position, state, and/or condition as a result of adjustment, if appropriate or desired.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

The inventions disclosed herein are described in the context of a photovoltaic module. However, these inventions can be used in other contexts as well.

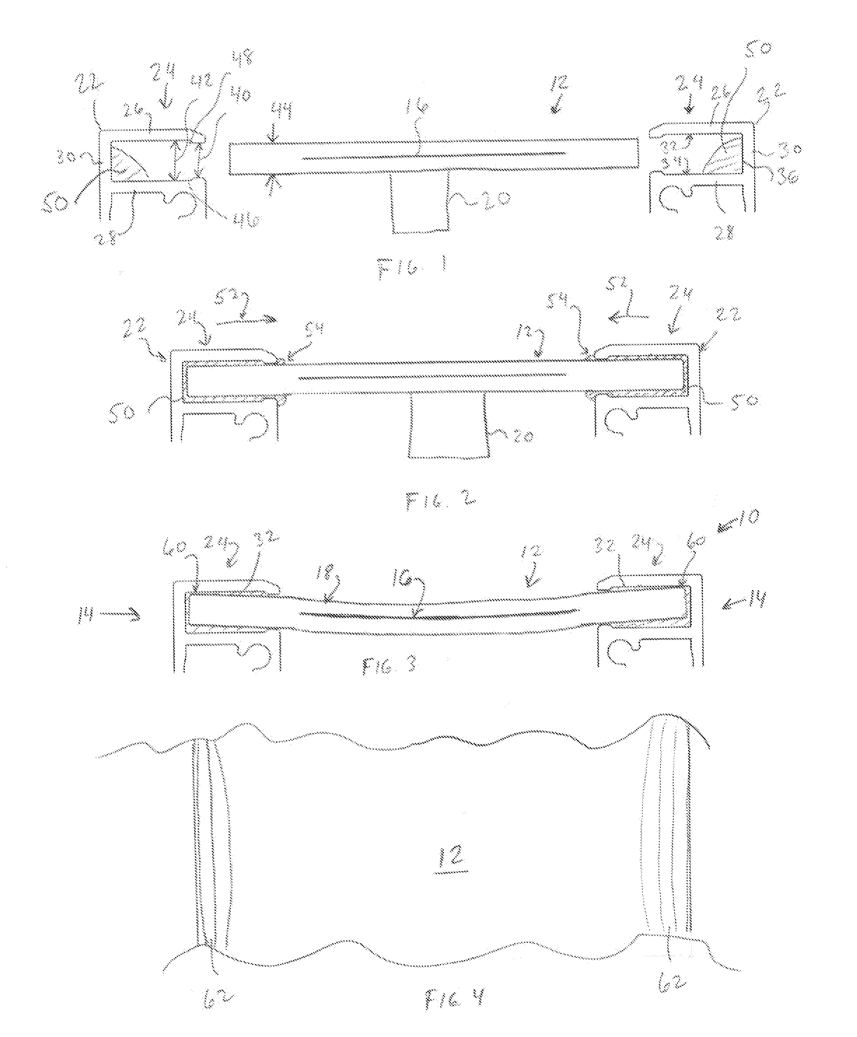

FIGS. 1-4 illustrate a process and results of certain aspects of manufacturing of photovoltaic module 10. The photovoltaic module 10 (FIG. 3) can include a photovoltaic device 12 and a frame 14 (FIG. 10).

With continued reference to FIGS. 1-4, the photovoltaic device 12, known as a “PV laminate”, typically includes an array of photovoltaic cells 16 which can be imbedded in an encapsulate material. The cell 16 can be further protected with one or more layers of glass 18 bonded to the upper end or lower sides of the cell 16, in a known manner. The glass 18 can be considered as providing a weatherproof barrier for the cell 16. The PV cells 16 can comprise backside-contact cells, such as those of the type available from Sun Power Corporation, of San Jose, Calif.

Such backside contact cells can include wiring (not shown) leading to external electrical circuits on the backside of the laminate 12 (i.e., the side facing away from the sun upon insulation) for providing an increased area for solar collection. Backside contact cells are also disclosed in U.S. Pat. Nos. 5,053,083 and 4,927,770, which are both incorporated herein by reference in their entirety. Other types of PV cells may also be used without detracting from the merits of the inventions disclosed herein. For example, the photovoltaic cell 16 can incorporate thin film technology, such as silicone thin films, non-silicone devices (e.g., III-V cells including GaAs, etc). Thus, while not shown in the figures, in some embodiments, the PV device 12 can include one or more components in addition to the PV laminate 12, such as wiring or other electrical components.

With reference of FIGS. 1-4, a photovoltaic module 10 can be manufactured by bonding the frame 14 to the laminate 12. For example, as shown in FIG. 1, a PV laminate 12 can be supported by below by a support fixture 20. Frame members 22, which form the frame 14, can include a channel portion 24. The channel portion can include an upper wall portion 26, a lower wall portion 28 and a bight portion 30, connecting the upper wall portion and the lower wall portion 26, 28 at an inner portion of the channel portion 24. The wall portions 26, 28 can also be considered as flanges.

The upper wall portion 26 can include an inner wall surface 32 and the lower wall portion 28 can include an inner surface 34. Similarly, the bight portion 30 can also include an inner surface 36.

The distal most portions of the inner surfaces 32, 34 can define a mouth portion having a spacing 40 that is smaller than the spacing 42 between the inner surface 32, 34 in the remainder of the interior of the channel portion 24.

The laminate can have a thickness 44 that is slightly smaller than the mouth portion 40. For example, the mouth portion 40 can provide a clearance relative to the thickness 44 so as to provide a sufficient amount of adhesive to cure therein to achieve a desired bond strength.

The extra clearance provided by the spacing 42 and the remainder of the channel portion 24 can provide an additional benefit in reducing a defect that can be formed during the curing process, described below. Further, the change in height between the spacing 42 to the spacing of the mouth 40 can create wells 46, 48 that help retain liquid adhesive within the channel portion 24 during the assembly process, described below.

One technique for attaching the channel portion 24 of the frame members 22 to the laminate 12 is to dispense a bead of liquid adhesive 50 into the channel portion 24, and then with reference to FIG. 2, press the frame members 22 inwardly, in the direction of arrows 52 so as to move the channel portions 24 over the peripheral edges of the laminate 12.

During the process of moving the frame members 22 inwardly, over the peripheral edges of the laminate 12, the liquid adhesive 50 spreads around the upper, lower and outer surfaces of the periphery of the laminate 12, as well as over the inner surfaces 32, 34, 36 of the channel portions. Additionally, the relatively reduced spacing 40 of the mouth portion 40 helps retain the liquid adhesive within the channel portion and reduces leaking out of the liquid adhesive 50, were also known as “ooze out”, identified by the reference numeral 54.

With reference to FIG. 3, in order to allow the adhesive 50 to cure, the combined laminate 12 and frame 14 can be removed from the support 20 and allowed to cure with the laminate 12 supported by the frame 14.

The added volume provided by the enlarged spacing 42 relative to the mouth portion 40, provides for an additional amount of adhesive to remain in the channel portion 24 compared to certain prior art designs. For example, some known prior art designs do not include a mouth portion and an enlarged spacing of the corresponding inner surfaces of such prior art designs. Rather, some of those known designs include channel portions that have uniformly flat walls spaced so as to provide the optimal thickness for the corresponding liquid adhesive.

However, it has been found that during the curing process, as is shown with exaggeration in FIG. 3, the weight of the laminate 12 causes the laminate 12 to sag downwardly (e.g., in its center) and thereby bending the outer peripheral edges of the laminate 12 upwardly.

In FIG. 3, the uppermost outer peripheral edges of the laminate 12 are identified by the reference numerals 60. These uppermost portions 60 can become pressed against the inner surfaces 32 of the channel portion 24.

With the reference to FIG. 4, when the laminate 12 is bent as such, these uppermost portions 60 cause the liquid adhesive 50 to flow away from these areas 60, which can thereby generate areas of thinner liquid adhesive 62 (FIG. 4). These areas of thin adhesive 62 are smaller than the areas that can be generated in the prior art designs noted above, in which the channel portions 42 do not include an enlarged spacing 42 inward from a mouth portion 40 of the frame.

Thus, by providing the enlarged spacing 42 relative to the spacing of the mouth portion 40, the size of the thinned portion 62 of the adhesive 50 can be reduced. Thus, the enlarged spacing 42 helps to overcome defects formed by the uppermost portion 60 of the laminate 12 during the curing process.

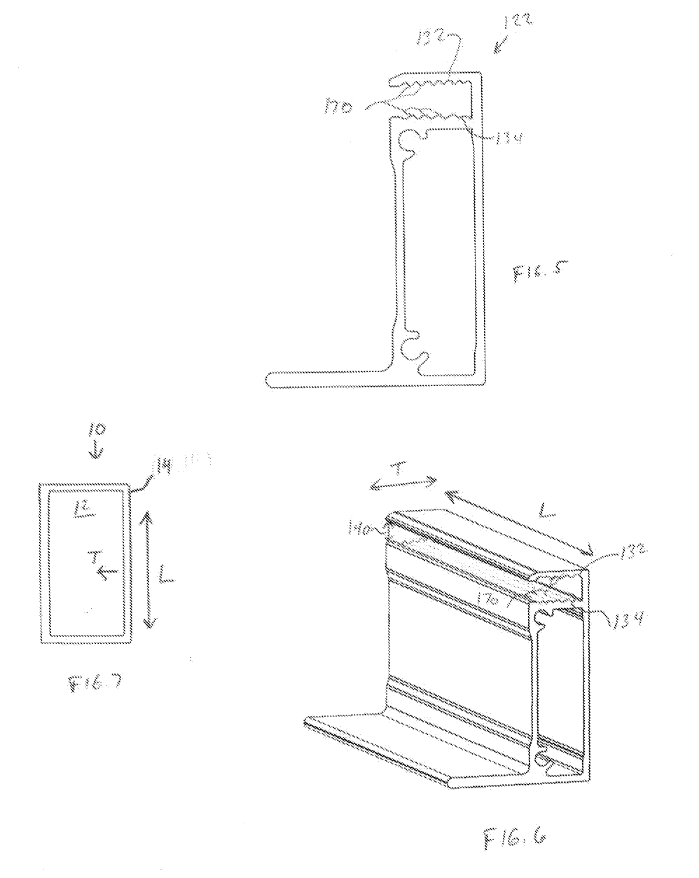

With reference to FIGS. 5 and 6, a further embodiment of the frame member 22 is illustrated therein and is identified by the reference numeral 122. The components of the frame members 122 that are the same or similar to the components or features of frame members 22 are identified with the same reference numeral, except that 100 has been added thereto.

As shown in FIGS. 5 and 6, the frame numbers 122 include a plurality of longitudinally surface features 170 on at least one of the inner surfaces 132, 134. In the illustrated embodiment, the surface features 170 extend longitudinally, and continuously, on both of the inner surfaces 132, 134.

The longitudinally extending surface features 170 can be in the form of ridges, or have other shapes. With reference to FIG. 6, the longitudinally extending surface features 170 extend generally parallel to a longitudinal direction L and generally transverse to a transverse direction T (FIGS. 6 and 7). As such, during the manufacturing process such as the process illustrated in FIGS. 1-4, the liquid adhesive 50 can be guided by the longitudinally extending surface features 170 to flow more in a longitudinal direction which can improve wetting of the peripheral edges of the laminate 12 and the inner surfaces 132, 134, 136 of the channel portion, and thus can also further help reduce ooze out 54 (FIG. 2).

In the illustrated embodiment, the longitudinally extending surface features 170 have a generally sinusoidal cross-sectional shape. The size and shape of the surface features 170 can be chosen to provide the desired increase in surface area. For example, with the surface features 170, the surface area of the upper and lower surfaces 132, 134 are greater than the surface areas of the surfaces 32, 34. In some embodiments, the magnitude and shape of the surface features 170 can be chosen to provide a surface area that is increased by about 20% relative to planar surfaces, such as surfaces 32, 34.

As shown in FIG. 7, using either the frame members 22, 122, a complete photovoltaic module 10 can be manufactured having a laminate enclosed by frame 14, wherein the frame extends around and is bonded to the peripheral edges of the laminate 12.

With reference to FIGS. 8-13, the surface features 170 can have various different shapes and sizes. For example, shown in FIG. 8, the surface features 170 can be formed only on the inner surface 134 of the lower member 28. The shape of the surface feature 170, as noted above, can be generally sinusoidal having a peak to peak spacing 176 of about 1 mm. Additionally, the peak height of the sinusoidal shape of the surface features 170, identified by the reference numeral 178, can also be about 1 mm. However, other shapes and sizes can also be used.

With the configuration of the surface features 170 illustrated in FIG. 8, the lower surface can be provided with about 20% more surface area compared to the lower surface 34. As such, the strength of the resulting adhesive bond between the laminate 12 and the inner surface 134 can be approximately 20% stronger.

Further, a minimum spacing 142 between the peaks of the surface feature 170 on the inner surface 134 and the inner surface 132 can be larger than the mouth portion 140. This minimal spacing is identified by the reference numeral 142.

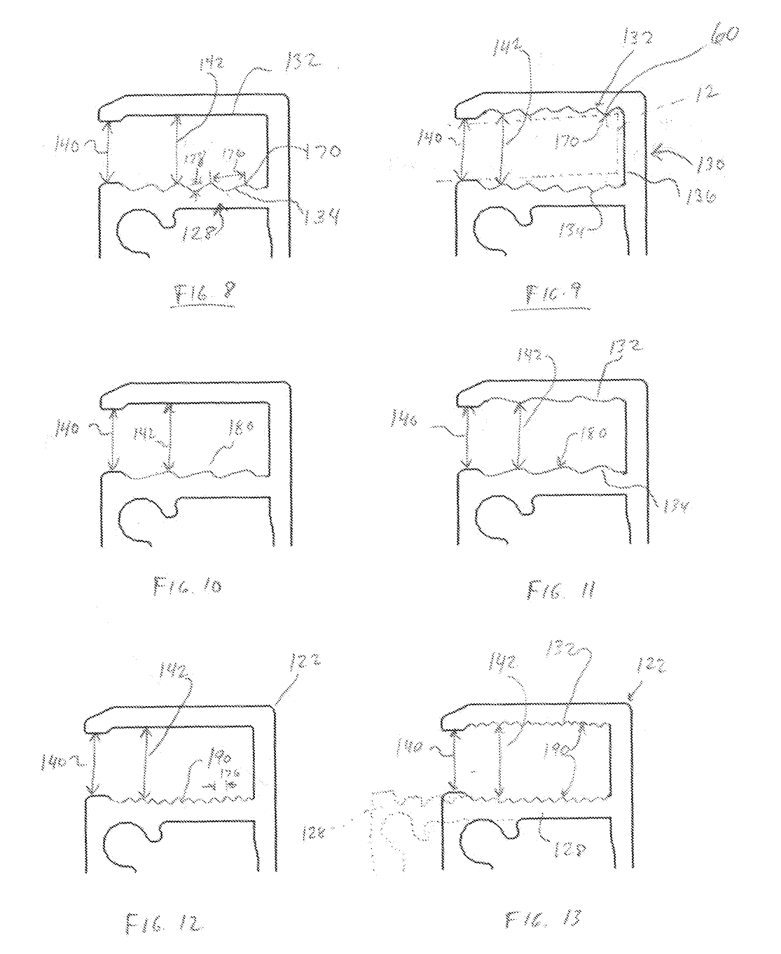

With reference to FIG. 9, in a similar arrangement, the inner surface 132 can also include an arrangement of surface features 170. Although not illustrated, the inner surface 136 of the bight portion 130 can also include surface features of desired period.

With the arrangement of FIG. 9, when the laminate 12 (illustrated in phantom line) is subject to the curing process, the maximum height portion 60 of the laminate 12 are pressed against a peak of one of the surface features 170. More specifically, a downward facing peak. Due to the curved shape of the peak of the surface feature 170, the resulting area of minimum spacing between the laminate 12 and the peak of the surface feature 170 is smaller, i.e. narrower in the transverse direction T, compared to the thinned area 62 (FIG. 4). Thus, the defect associated with the upper surface of the laminate 12 being bent upwardly toward the inner surface 132, is further reduced.

With reference to FIGS. 10 and 11, further embodiments of the surface features 170 are illustrated therein. As shown in FIG. 10, the inner surface 134 can include surface features 180 that include a generally ramped or saw toothed shape. As shown in FIG. 11, both of the inner surfaces 132, 134 can include the surface features 180. Further, optionally, whether or not the surface features 180 are provided on both surfaces 132, 134, the enlarged spacing 142 relative to the mouth portion 140 can be maintained.

Further, as shown in FIGS. 12 and 13, the frame number 122 can include surface features 190 than of a significantly smaller cross-sectional shape than the surface features 170, 180. For example, in the illustrated embodiment, the surface features 190 have a generally sinusoidal shape, however, have a peak to peak spacing 176 of a fraction of a millimeter, such as about 1/10 mm. Similarly, the height of the sinusoids forming the surface features 190 can be approximately the same, about 0.1 mm. As with the above embodiments, the inner surface 132 can also include the surface features 190. Similarly, the enlarged spacing 142 relative to the spacing of the mouth portion 140 can also be maintained.

Optionally, with regard to all of the embodiments disclosed in FIGS. 1-13, the lower wall 28, 128 (or “flange”) can be longer then the corresponding upper wall 26, 126. This configuration can provide a benefit in increased bonding strength with the lower surface of the laminate 12 without increasing the amount of ovelap, and therefore shadow, on the upper surface of the laminate 12.

Also optionally, with regard to all of the embodiments disclosed in FIGS. 1-13, the surface features 170 can be non-continuous surface features having any shape or configuration. For example, the surface features 170 can be in the shape of individual bumps distributed over the inner surfaces of the channel portion of the frame members 22, 122.

the lower wall 28, 128 (or “flange”) can be longer then the corresponding upper wall 26, 126. This configuration can provide a benefit in increased bonding strength with the lower surface of the laminate 12 without increasing the amount of ovelap, and therefore shadow, on the upper surface of the laminate 12.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A photovoltaic solar collector comprising:
a photo electronic device configured to convert solar radiation into electrical power, the photo electronic device having a photo-sensitive surface arranged to be exposable to sunlight and a peripheral edge; and
at least a first frame member connected to the peripheral edge of the photo electronic device, the first frame member comprising at least a first surface bonded to the peripheral edge of the photo electronic device, at least one of the peripheral edge and the first surface being non planar.

2. The photovoltaic solar collector according to claim 1, wherein the peripheral edge is planar and the first surface is non-planar.

3. The photovoltaic solar collector according to claim 2, wherein the first surface comprises longitudinally extending surface features bonded to the peripheral edge.

4. The photovoltaic solar collector according to claim 1, wherein the frame comprises a channel portion having first and second flanges, the first surface being an inner facing surface of the first flange.

5. The photovoltaic solar collector according to claim 4, wherein the first surface comprises surface features extending along a longitudinal direction of the peripheral edge of the photo electronic device.

6. The photovoltaic solar collector according to claim 5, wherein the surface features comprises a plurality of longitudinally extending ridges.

7. The photovoltaic solar collector according to claim 5, wherein the channel comprises a mouth portion disposed at distal ends of the first and second flanges, a spacing between the first and second flanges at the mouth portion being smaller than a spacing between the first and second flanges at proximate portions of the first and second flanges.

8. The photovoltaic solar collector according to claim 5, wherein the surface features provide the first surface with greater surface area.

9. The photovoltaic solar collector according to claim 5, wherein the surface features comprise sinusoidal cross sections.

10. The photovoltaic solar collector according to claim 5, wherein the surface features comprise saw-tooth cross sections.

11. The photovoltaic solar collector according to claim 4, wherein the first flange is a lower flange of the channel portion and the second flange is an upper flange of the channel portion, the first flange being longer than the second flange.

12. The photovoltaic solar collector according to claim 11, wherein the upper flange includes longitudinally extending surface features.

13. A photovoltaic solar collector comprising:
a photo electronic device configured to convert solar radiation into electrical power, the photo electronic device having a photo-sensitive surface arranged to be exposable to sunlight and a planar peripheral edge having an upper peripheral edge surface and a lower peripheral edge surface; and
a frame extending longitudinally along the peripheral edge of the photo electronic device, the frame comprising a channel portion comprising an upper flange and a lower flange, the upper flange having an upper flange inner surface, the lower flange having a lower flange inner surface, at least one of the upper flange inner surface and the lower flange inner surface having longitudinally extending ribs sized and shaped so as to increase the surface area of the inner surface compared to a planar surface having a same footprint, the upper and lower flange inner surfaces being bonded to the upper and lower peripheral edge surfaces, respectively.

14. The photovoltaic solar collector according to claim 13, wherein both of the upper and lower flange inner surfaces comprise longitudinally extending ribs bonded to the upper and lower peripheral edge surfaces.

15. The photovoltaic solar collector according to claim 13, wherein the longitudinally extending ribs comprise substantially sinusoidal cross sectional shapes.

16. The photovoltaic solar collector according to claim 13, wherein the channel portion comprises a bight portion connecting the upper and lower flanges, the channel portion further comprising a mouth portion at a distal end of the channel portion, a first spacing between the upper and lower flanges at the mouth portion being smaller than a second spacing between the upper and lower flanges at a proximate portion of the channel portion.

17. The photovoltaic solar collector according to claim 16, wherein the second spacing is defined by the crests of the longitudinally extending ribs.

18. A photovoltaic solar collector comprising:
a photo electronic device configured to convert solar radiation into electrical power, the photo electronic device having a photo-sensitive surface arranged to be exposable to sunlight and a planar peripheral edge; and
a frame extending longitudinally along the peripheral edge of the photo electronic device, the frame comprising a channel having an inner surface bonded to the planar peripheral edge, and means for providing increased surface area of the inner surface of the channel that is bonded to the peripheral edge.

19. The photovoltaic solar collector according to claim 18, wherein the channel comprises upper and lower inner surfaces, both of which include means for providing increased surface area of the inner surface of the channel that is bonded to the peripheral edge.

20. The photovoltaic solar collector according to claim 18, additionally comprising means for guiding a flow of liquid adhesive longitudinally along the channel during insertion of the peripheral edge into the channel.
